(19) United States
(12) Patent Application Publication
(10) Pub. No.: US 2026/0098876 A1
(43) Pub. Date: Apr. 9, 2026

(54) PROBE FOR PROBE CARD

(71) Applicant: JAPAN ELECTRONIC MATERIALS CORPORATION, Amagasaki-shi, Hyogo (JP)

(72) Inventor: Hideki MUKAI, Amagasaki-shi, Hyogo (JP)

(73) Assignee: JAPAN ELECTRONIC MATERIALS CORPORATION, Amagasaki-shi, Hyogo (JP)

(21) Appl. No.: 19/113,865

(22) PCT Filed: Sep. 21, 2022
(86) PCT No.: PCT/JP2022/035187

§ 371 Date: Mar. 20, 2025

(51) Int. Cl. G01R 1/067; G01R 1/073

(52) U.S. Cl. CPC G01R 1/0675; G01R 1/06755; G01R 1/07342; G01R 1/07357

(57) ABSTRACT

This probe for a probe card has, on a reference surface perpendicular to a buckling direction a plurality of deformed regions which are arranged with spacings therebetween, the outer edge of which is circular, oval, or polygonal, and which has a recessed shape or a protruding shape, and a framework region, which is provided at the boundary of adjacent deformed regions. A plurality of the deformed regions are arranged with spacings therebetween in rows in a prescribed direction relative to the lengthwise direction of the probe, and a plurality of the rows are arranged with spacings therebetween in the lengthwise direction of the probe.

### TECHNICAL FIELD

The present disclosure relates to a probe for a probe card.

### BACKGROUND ART

A probe card is an electrical connection device used to supply power, input and output signals, and provide grounding by bringing probes into contact with electrode pads of semiconductor devices in order to perform operational testing of individual semiconductor devices formed on a wafer.

The probes are provided on a surface of the probe card and are configured such that tip portions thereof are pressed against the electrode pads of semiconductor devices with a predetermined pressing force.

To increase the number of semiconductor devices formed on a wafer, it is necessary to reduce the size of semiconductor devices. Accordingly, electrode pads of semiconductor devices are designed smaller, and distances (pitches) between the electrode pads are also reduced.

As semiconductor devices become smaller, probes must also be miniaturized accordingly. However, when the probes are miniaturized, a problem arises in that the mechanical strength of the probes decreases.

Therefore, in order to ensure good electrical and mechanical contact with the electrode pads of semiconductor devices, for example, Patent Document 1 proposes a structure in which a multilayer metal sheet is used for the probe.

### CITATION LIST

### Patent Document

[Patent Document 1] Japanese Laid-Open Patent Publication No. 2018-501490

### SUMMARY OF THE INVENTION

### Problem to be Solved by the Invention

The probe disclosed in Patent Document 1 includes at least one multilayer structure comprising a core and a first inner coating layer laminated thereon, and an outer coating layer made of a material having higher hardness than the core, which completely covers the multilayer structure.

As disclosed in Patent Document 1, in order to achieve good electrical and mechanical contact, it is preferable to use a multilayer metal sheet composed of different materials. However, there is a limit to reducing the thickness of the cross-section of the probe, and further breakthroughs were necessary.

In an inspection process using a probe card, in order to ensure contact with the electrode pads of semiconductor devices, after the probes make contact with the electrode pads, the probe card is further brought closer to a semiconductor wafer (overdrive), thereby pressing the probes against the electrode pads of the semiconductor devices.

Therefore, the probes must have sufficient strength so as not to be damaged even when a contact pressure exceeding a certain threshold is applied. In order to prevent damage, it is necessary to avoid localized stress concentration in the probes. To achieve this, probes with as smooth and scratch-free surfaces as possible have been required.

However, there is a limit to how smooth a metal surface can be made, and the thinner the cross-sectional thickness of the probe, the more easily the probe deforms under external force, resulting in decreased mechanical strength.

The present disclosure provides a technique to solve the above-described problems, and an object of the present disclosure is to provide a probe that, even when miniaturized, is capable of contacting the electrode pads of semiconductor devices with an appropriate needle pressure and has sufficient strength to withstand an applied contact pressure beyond a certain threshold without damage.

That is, the probe for a probe card according to the present disclosure is not designed to eliminate stress concentration, but rather to intentionally distribute positions where stress concentration occurs, thereby providing a probe for a probe card with high mechanical strength that can withstand high stress.

### Means to Solve the Problem

The probe for a probe card, wherein the probe is a vertical probe that buckles in a direction perpendicular to the longitudinal direction of a conductive metal plate disclosed in the present disclosure includes: a plurality of deformed regions arranged with spacings therebetween on the reference surface included in the plate surface perpendicular to a buckling direction, the outer edge of each deformed region being circular, ellipse, or polygonal, and the deformed region having a recessed shape or a protruding shape; and a framework region provided at the boundary of adjacent deformed regions. A plurality of the deformed regions are arranged as a row with spacings therebetween in a predetermined direction relative to the lengthwise direction of the probe, and a plurality of the rows are arranged with spacings there between. The plurality of deformed regions in the N-th row and the plurality of deformed regions in the (N+1)-th row are staggered along the predetermined direction.

### Effect of the Invention

According to the probe for a probe card disclosed in the present specification, even if the plate thickness is reduced, it is possible to provide a probe for a probe card with high mechanical strength and a method for manufacturing the probe for a probe card by distributing the positions where stress concentration occurs.

### BRIEF DESCRIPTION OF THE DRAWINGS

FIG. 1 is a perspective view showing a schematic structure of a probe for a probe card according to Embodiment 1.

FIG. 2 is a diagram showing the relationship between the overdrive amount and the needle pressure of the probe according to Embodiment 1.

FIG. 3 is a diagram showing the relationship between the overdrive amount and the stress acting on the probe according to Embodiment 1.

FIG. 4 is a cross-sectional view showing the framework region when a large number of recesses are provided in Embodiment 1.

FIG. 5A is a diagram showing the manufacturing process of the probe by electroplating in Embodiment 1.

FIG. 5B is a diagram showing the manufacturing process of the probe by electroplating in Embodiment 1.

FIG. 6 is a diagram showing the manufacturing method of the probe by pressing in Embodiment 1.

FIG. 7 is an enlarged partial view of a surface perpendicular to the buckling direction X of a probe according to Embodiment 2.

FIG. 8 is a diagram showing the surface where deformed regions are provided in the probe according to Embodiment 2.

FIG. 9 is an enlarged partial view of a surface perpendicular to the buckling direction X of a probe according to Embodiment 3.

FIG. 10 is an enlarged partial view of a surface perpendicular to the buckling direction X of a probe according to Embodiment 4.

FIG. 11 is an enlarged partial view of a surface perpendicular to the buckling direction X of a probe according to Embodiment 5.

FIG. 12 is a diagram showing a modified example of Embodiment 5.

FIG. 13 is an enlarged partial view of a surface perpendicular to the buckling direction X of a probe according to Embodiment 6.

FIG. 14 is an enlarged partial view of a surface perpendicular to the buckling direction X of a probe according to Embodiment 7.

FIG. 15A is an enlarged partial view of a surface perpendicular to the buckling direction X of a probe according to Embodiment 8.

FIG. 15B is a cross-sectional view along line B-B in FIG. 15A.

FIG. 16 is a diagram showing a partial cross-sectional shape of a probe according to Embodiment 9.

### DESCRIPTION OF EMBODIMENTS

### Embodiment 1

A probe for a probe card according to Embodiment 1 will be described with reference to the drawings. In the drawings below, the same or corresponding components are denoted by the same reference numerals.

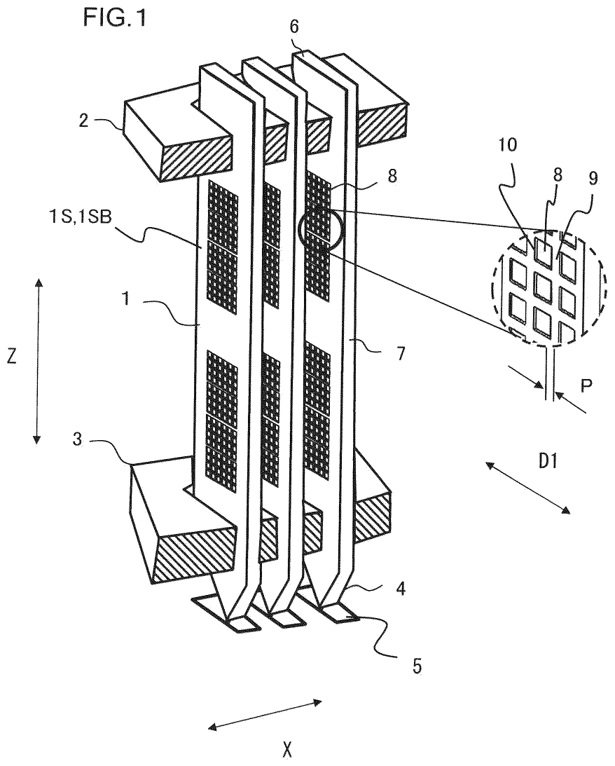

FIG. 1 is a perspective view showing the structure of a probe 1 for a probe card.

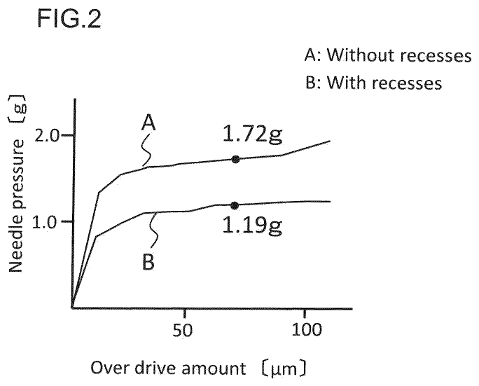

FIG. 2 is a diagram showing the relationship between the overdrive amount and the needle pressure of the probe 1.

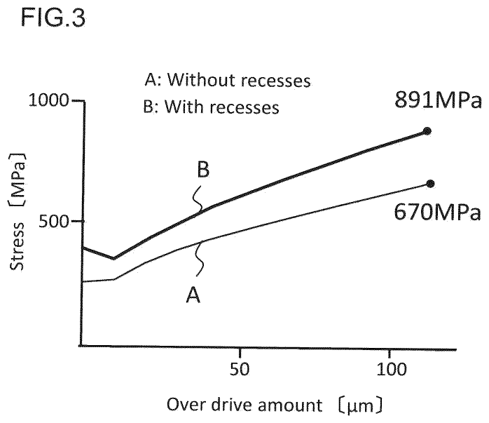

FIG. 3 is a diagram showing the relationship between the overdrive amount and the stress acting on the probe.

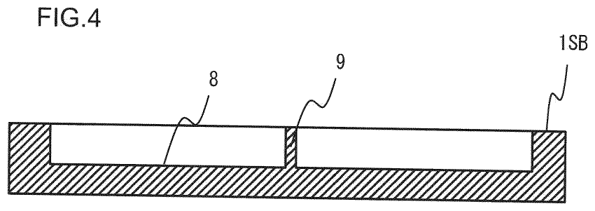

FIG. 4 is a partial cross-sectional view of deformed regions 8 and a framework region 9.

The probe 1 is a so-called vertical probe that is held approximately vertically by an upper first guide plate 2 and a lower second guide plate 3. The tip portion 4 of the probe 1 is guided by the second guide plate 3 so as to contact an electrode pad 5 of a semiconductor device. The rear-end portion 6 (upper side in FIG. 1) of the probe 1 is guided by the first guide plate 2 so as to be connected to an electrode (not shown) that leads to a circuit board of the probe card.

The probe 1 is formed of a thin metal plate made of a conductive material, and at least one of the surfaces 1S (front or back) perpendicular to the buckling direction X in the central portion 7 of the probe 1 is provided with multiple deformed regions 8 and a framework region 9. The buckling direction X is the direction in which the probe 1 bends during the so-called overdrive of the probe card.

The deformed region 8 refers to a region where the reference surface 1SB, which was originally a flat plane of the probe card, is deformed to form a recess. The framework region 9 refers to the region connecting among the multiple deformed regions 8. The boundary between the deformed region 8 and the framework region 9 is represented as a ridge 10.

FIG. 1 shows an example in which recesses with a rectangular prism shape are provided as deformed regions 8 on the reference surface 1SB, which was originally a flat plane. When viewed in the buckling direction X of the probe 1, the outer edge of the deformed region 8 is therefore rectangular. The framework region 9 corresponds to the planar portions between the deformed regions 8. A plurality deformed regions 8 are arranged in a predetermined direction D1 in a row relative to the longitudinal direction Z of the probe 1, with spacings P, and multiple rows are arranged. The spacing P corresponds to the width of the framework region 9. In this Embodiment 1, the direction D1 is set to be perpendicular to the longitudinal direction Z of the probe 1.

A comparison was conducted between a probe structure without any deformed regions 8 and a probe structure with deformed regions 8 provided on both the front and back surfaces. The results obtained are as follows: When measuring the characteristics, the measurement results for a probe without deformed regions 8 on the surface are denoted as A, and the measurement results for a probe 1 with deformed regions 8 are denoted as B. As shown in FIG. 2, in an overdrive state where the tip portion 4 of the probe 1 contacts the electrode pad 5 and is further pressed against it, the relationship between the overdrive amount and the needle pressure was as shown. Furthermore, as shown in FIG. 3, the relationship between the overdrive amount and the stress was also obtained.

As shown in FIG. 2, when the overdrive amount was 70 μm, the needle pressure was 1.72 gf for a probe without recess-shaped deformed regions 8, whereas it was 1.19 gf for a probe 1 with recess-shaped deformed regions 8.

Additionally, as shown in FIG. 3, when the overdrive amount was 110 μm, the maximum stress was 670 MPa for a probe without recesses, whereas it was 891 MPa for a probe 1 with recess-shaped deformed regions 8, confirming that the mechanical characteristics of the probe were satisfied.

An analysis of why the maximum stress increased suggests that the difference in the surface area of the probe 1 is a structural factor. That is, by providing rectangular prism-shaped deformed regions 8 on the surface of the probe 1, the surface area increases.

When forming a recessed shape by depressing a square plane, the surface area of the bottom surface of the rectangular prism remains unchanged as it is merely pushed downward. However, the surface area of the inner wall formed by the cave-in increases.

In FIG. 1, the recesses provided on the front and back surfaces of the probe are squares with a side length of 20 μm, with a recess depth of 3.5 μm on the front surface and 2.5 μm on the back surface. A total of 429 recesses are provided on both the front and back surfaces. As a result, the surface area increased by 120, 120 μm² on the front side and 85,800 μm² on the back side. The surface area increases due to the inner walls formed by the cave-in. Here, since larger recesses would affect the thickness of the probe 1, it is preferable to achieve a larger surface area by providing a large number of small recesses. By designing the size and arrangement of the recesses, the surface area can be adjusted as needed.

Furthermore, an analysis was conducted to determine the effects of the deformed regions 8. A probe A with a smooth surface (no recesses), a probe B with rectangular prism-shaped recesses arranged in a matrix, a probe C with rectangular prism-shaped recesses arranged in a staggered pattern, and a probe D with spherical recesses arranged in a staggered pattern were analyzed using the Finite Element Method (FEM). The results for the needle pressure and maximum stress of the probes are summarized in Table 1.

TABLE 1
Table 1 FEM Results

| | | | Probe C | |
|---|---|---|---|---|
| | | | Rectangular | Probe D |
| | | Probe B | Prism | Spherical |
| | Probe A | Rectangular | Deformed | Deformed |
| | No | Prism | Region | Region |
| | Deformed | Deformed | (Staggered | (Staggered |
| | Region | Region | Arrangement) | Arrangement) |
| Increase in | Baseline | +205920 | Same as | +169260 |
| Surface | | | Left | |
| Area | | | | |
| [μm²] | | | | |
| Needle | 1.72 | 1.19 | 1.18 | 1.18 |
| Pressure | | | | |
| [gf] | | | | |
| Maximum | 670 | 891 | 899 | 1164 |
| Stress | | | | |
| [MPa] | | | | |

As shown in Table 1, in the case of Probe A, the needle pressure was 1.72 gf when the overdrive amount was 70 μm, and the maximum stress was 670 MPa when the overdrive amount was 110 μm. In contrast, under the same conditions:
Probe B had a needle pressure of 1.19 gf and a maximum stress of 891 MPa.
Probe C had a needle pressure of 1.18 gf and a maximum stress of 899 MPa.
Probe D had a needle pressure of 1.18 gf and a maximum stress of 1164 MPa.

Additionally, stress contour maps (contour diagrams representing the calculation results as isopleths) were created for Probe A, Probe B, Probe C, and Probe D. Probe A had a maximum stress of 670 MPa, which was almost uniformly distributed. Probe B had a stress of 74 MPa on the flat bottom surface of the deformed region 8 and 668 MPa in the framework region 9, with a maximum stress of 891 MPa. Probe C had a stress of 74 MPa on the flat bottom surface of the deformed region 8 and 674 MPa in the framework region 9, with a maximum stress of 899 MPa. Probe D had a stress of 97 MPa on the spherical bottom surface of the deformed region 8 and 873 MPa in the framework region 9, with a maximum stress of 1164 MPa.

From these results, when an external force was applied to Probe A, Probe B, Probe C, and Probe D, it was estimated that stress was concentrated on the ridges 10, which are the boundaries between the deformed regions 8 and the framework regions 9. Additionally, by shaping the bottom surface of the deformed regions 8 as a flat plane or a spherical shape, stress was concentrated on the ridges 10, which are the boundaries between the deformed regions 8 and the framework regions 9.

This indicates that when the deformed regions 8 are formed as polygonal recesses, stress concentration occurs at each vertex of the polygon. When an external force is applied, stress is distributed among the vertices.

Therefore, if the deformed regions 8 are formed as conical or pyramidal recesses, stress can be distributed not only to the outer vertices but also to the apex of the cone or pyramid.

In this case, stress concentration on the ridges 10, which are the boundaries between the deformed regions 8 and the framework regions 9, can be alleviated.

It should be noted that when the ridges 10 are polygonal, stress concentration occurs at each vertex. However, the greater the number of vertices, the less stress each individual vertex bears.

From this perspective, when the perimeter of the recess is circular, stress is distributed along its perimeter. As described for Probe D, a structure in which the deformed region 8 is formed as a spherical recess is considered the most effective for stress distribution, resulting in a probe with high mechanical strength.

Next, the manufacturing method of the probe 1 shown in FIG. 1 will be described.

There are three different methods for manufacturing the probe 1. The first method is electroplating.

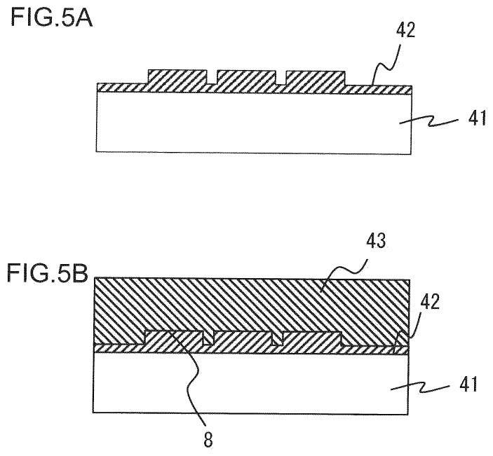

FIGS. 5A and 5B show the manufacturing process of the probe 1 by electroplating.

In this method:

A protruding shape corresponding to the recessed shape is formed using a conductive layer 42 on the surface of a substrate 41.

A metal layer 43, which forms the probe 1, is then deposited on the surface of the conductive layer 42, forming the deformed regions 8.

The metal layer 43 can be formed using electroplating.

The surface is then flattened, a mask is applied, and etching is performed to shape the probe.

Finally, the conductive layer 42 is removed, allowing the probe 1 to be detached from the substrate 41.

The second method is press molding.

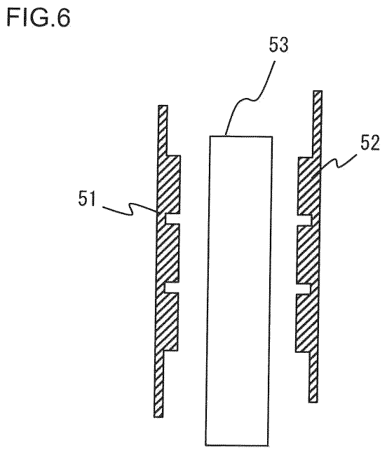

FIG. 6 shows the manufacturing method of the probe 1 using press molding. In this method:

A first mold 51 and a second mold 52, each having a surface corresponding to the recessed shape, are used.

A metal plate 53 is pressed from both sides, forming deformed regions 8 on its surfaces.

This pressing method has the advantage of a shorter manufacturing time compared to electroplating, which requires metal layer formation.

Although Embodiment 1 describes a structure in which the deformed regions 8 are formed as recesses, the same effect can be achieved by forming them as protrusions instead. The manufacturing process remains essentially the same, with recesses and protrusions simply reversed.

### Embodiment 2

Hereinafter, a probe for a probe card according to Embodiment 2 will be described, focusing on the parts different from Embodiment 1.

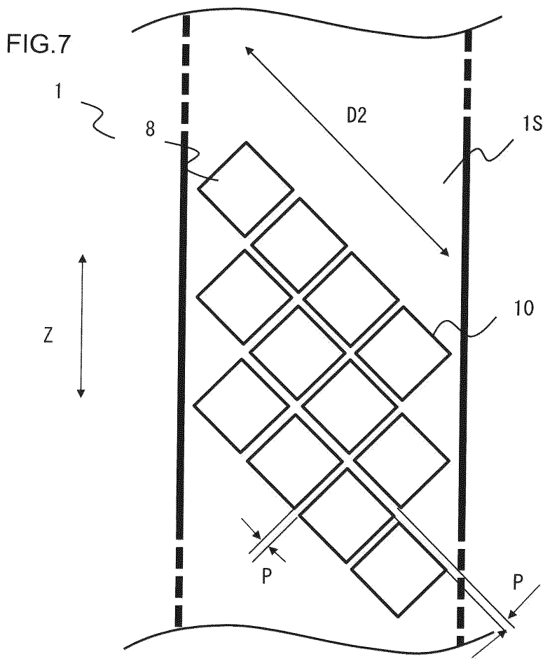

FIG. 7 is an enlarged view of an important portion of a surface 1S, which is perpendicular to the buckling direction X, of the probe 1. It shows another arrangement example of the deformed regions 8.

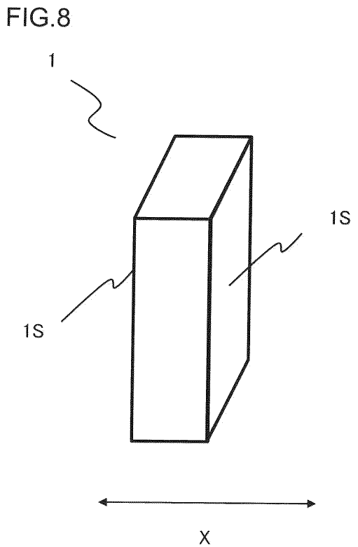

FIG. 8 shows the surface of the probe 1 where the deformed regions 8 are provided.

Similar to Embodiment 1, the deformed regions 8 are provided on at least one of the surfaces 1S, which are perpendicular to the buckling direction X, of the probe 1.

A plurality deformed regions 8 are arranged in a predetermined direction D2 in a row relative to the longitudinal direction Z of the probe 1, with spacings P, and multiple rows are arranged. Here, the direction D2 is set to be oblique relative to the longitudinal direction Z of the probe 1.

Each deformed region 8, when viewed in the buckling direction X, has a ridge 10 that is square. Therefore, its actual shape is a square prism, square pyramid, or truncated square prism, which is either a recess or a protrusion. The two opposing sides of the square ridge 10 of the deformed region 8 are arranged parallel to the predetermined direction D2, while the other two sides are arranged perpendicular to direction D2.

The spacing between adjacent deformed regions 8 in the direction perpendicular to direction D2 is also the same as spacing P. In this embodiment 2, the deformed regions 8 are arranged in straight, evenly spaced along the longitudinal direction Z of the probe 1 as well. The deformed regions 8 in the shape of a truncated cone, truncated elliptical cone, or truncated polygonal pyramid have a cross-sectional area that gradually increases toward the reference surface 1SB.

According to the probe for a probe card of embodiment 2, similar to embodiment 1, by regularly arranging deformed regions 8 of the same shape, stress can be regularly distributed, enabling the provision of the probe for a probe card with high mechanical strength.

### Embodiment 3

Hereinafter, a probe for a probe card according to embodiment 3 will be described, focusing on differences from embodiment 1.

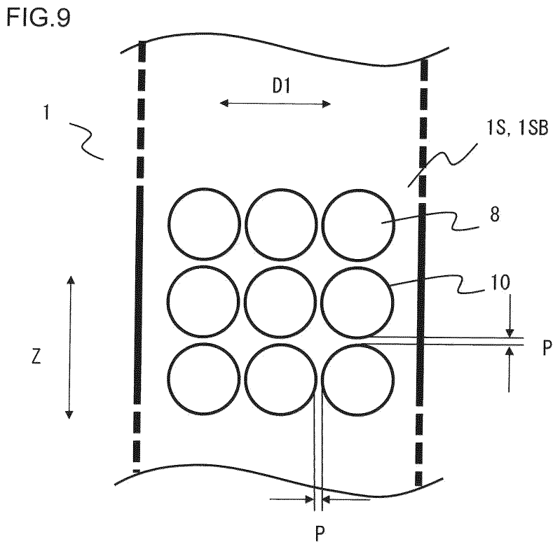

FIG. 9 is an enlarged partial view of the surface 1S of probe 1 perpendicular to the buckling direction X, showing another arrangement example of deformed regions 8.

A plurality deformed regions 8 are arranged in a predetermined direction D1 in a row relative to the longitudinal direction Z of the probe 1, with spacings P, and multiple rows are arranged. Here, the direction D1 is set to be perpendicular to the longitudinal direction Z of the probe 1.

Each deformed region 8, when viewed in the buckling direction X, has a ridge 10 (outer edges) that is circular (a kind of ellipse). Therefore, its actual shape is a cylinder, cone, truncated cone, or spherical recess or protrusion. The spacing between adjacent deformed regions 8 along the longitudinal direction Z of the probe 1 is also the same as spacing P.

According to the probe for a probe card of embodiment 3, similar to embodiments 1 and 2, by regularly arranging deformed regions 8 of the same shape, stress can be regularly distributed, enabling the provision of the probe for a probe card with high mechanical strength.

### Embodiment 4

Hereinafter, a probe for a probe card according to embodiment 4 will be described, focusing on differences from embodiment 2.

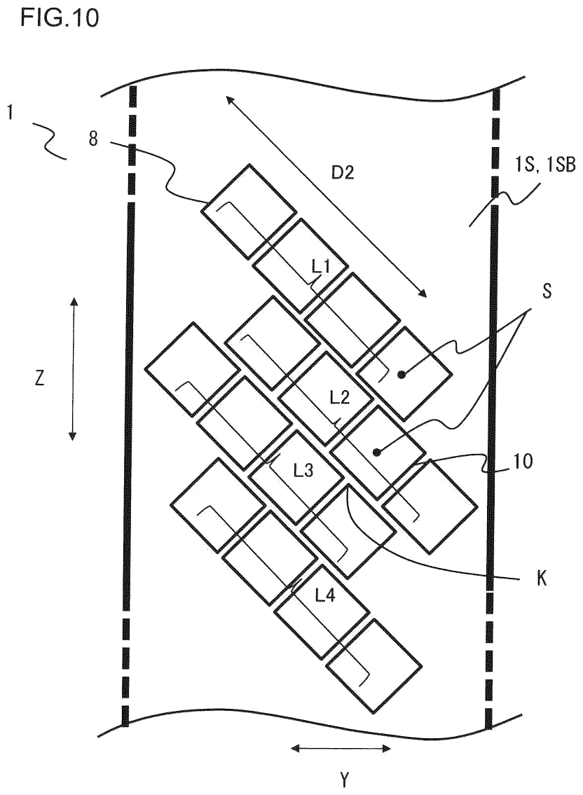

FIG. 10 is an enlarged partial view of the surface 1S of probe 1 perpendicular to the buckling direction X, showing another arrangement example of deformed regions 8. Similar to embodiment 2, the deformed regions 8 are provided on at least one of the surfaces 1S of probe 1 perpendicular to the buckling direction X.

A plurality deformed regions 8 are arranged in a predetermined direction D2 in a row relative to the longitudinal direction Z of the probe 1, with spacings P, and multiple rows are arranged. Here, the direction D2 is set to be oblique relative to the longitudinal direction Z of the probe 1.

Each deformed region 8, when viewed in the buckling direction X, has a ridge 10 (outer edge) that is square. Therefore, its actual shape is a square prism, square pyramid, or truncated square pyramid, which is either a recess or a protrusion.

The two opposing sides of the square ridge 10 (outer edge) of the deformed region 8 are arranged parallel to the predetermined direction D2, while the other two sides are arranged perpendicular to the direction D2. The spacing between adjacent deformed regions 8 in the direction perpendicular to direction D2 is also the same as spacing P. The difference from embodiment 2 is that in embodiment 2, the deformed regions 8 were arranged in straight, evenly spaced rows along the longitudinal direction Z of the probe 1, whereas in this embodiment 4, the deformed regions 8 are not arranged in straight rows along the longitudinal direction z of the probe 1.

As shown in FIG. 10, the first row L1, second row L2, third row L3, and fourth row L4 each consist of four deformed regions 8 (though in practice, there are more). The deformed regions 8 of the first row L1 and the deformed regions 8 of the second row L2 are arranged in a staggered manner along direction D2. The same applies to the deformed regions in the second row L2 and the third row L3. Furthermore, the centers S of all the deformed regions 8 in the first row L1 are not aligned in a straight line in the longitudinal direction Z of the probe 1 with the centers S of any of the deformed regions 8 in the second row L2.

When the deformed regions 8 are arranged in this manner, the second and subsequent deformed regions 8 in the Nth row, which form one side of ridge 10, face the ridge 10 of the deformed regions 8 in the (N+1)th row. The one side of the deformed region 8 in the Nth row that faces the deformed region 8 in the (N+1)th row aligns parallelly with two opposite sides forming the ridge 10 of the deformed regions 8 in the (N+1)th row. In other words, the corners K of two deformed regions 8 are positioned close together. It should be noted that the spacing between adjacent deformed regions 8 remains the same as in embodiment 2.

According to the probe for a probe card of embodiment 4, the corners K of the deformed regions 8, where stress is concentrated, are positioned close in pairs. Compared to embodiment 2, where four corners K were close together, this configuration effectively doubles the number of locations where stress is distributed. This further distributes stress and enables the provision of the probe for a probe card with higher mechanical strength.

### Embodiment 5

Hereinafter, a probe for a probe card according to embodiment 5 will be described, focusing on differences from embodiment 3.

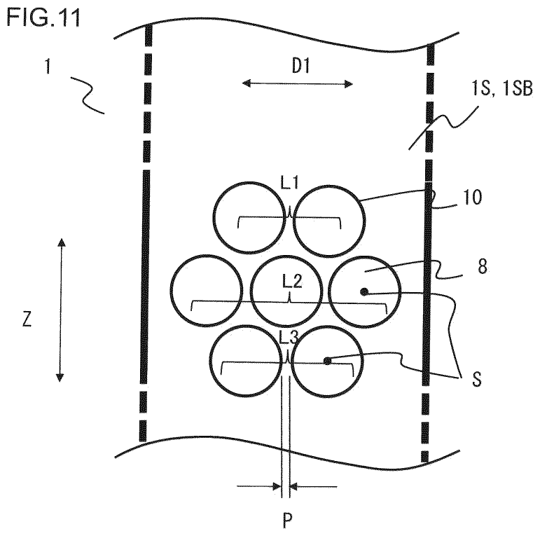

FIG. 11 is an enlarged partial view of the surface 1S of probe 1 perpendicular to the buckling direction X, showing another arrangement example of deformed regions 8. Similar to embodiment 3, the deformed regions 8 are provided on at least one of the surfaces 1S of probe 1 perpendicular to the buckling direction X.

A plurality deformed regions 8 are arranged in a predetermined direction D1 in a row relative to the longitudinal direction Z of the probe 1, with spacings P, and multiple rows are arranged. Here, the direction D1 is set to be perpendicular to the longitudinal direction Z of the probe 1.

Each deformed region 8, when viewed in the buckling direction X, has a ridge 10 (outer edge) that is circular. Therefore, its actual shape is a cylinder, cone, or truncated cone, which is either a recess or a protrusion. The spacing between adjacent deformed regions 8 is uniform and remains equal to spacing P. The difference from embodiment 3 is that, in embodiment 3, the centers of the deformed regions 8 were aligned in straight, evenly spaced rows along the longitudinal direction Z of the probe 1, whereas in this embodiment 5, the deformed regions 8 are not aligned in a straight line along the longitudinal direction Z of the probe 1.

As shown in FIG. 11, the first row L1 consists of two deformed regions 8 (though in practice, there are more), while the second row L2 consists of three deformed regions 8. The third row L3 consists of two deformed regions 8. Thus, the number of deformed regions 8 in adjacent rows differs. As shown in FIG. 11, the deformed regions 8 of the first row L1 and the deformed regions 8 of the second row L2 are arranged alternately along direction D1. The same applies to the deformed regions in the second row L2 and the third row L3. Although the spacing between adjacent deformed regions 8 remains the same as in embodiment 3, a comparison of FIGS. 9 and 11 shows that this embodiment 5 allows for a higher-density arrangement of deformed regions 8 in the same surface area.

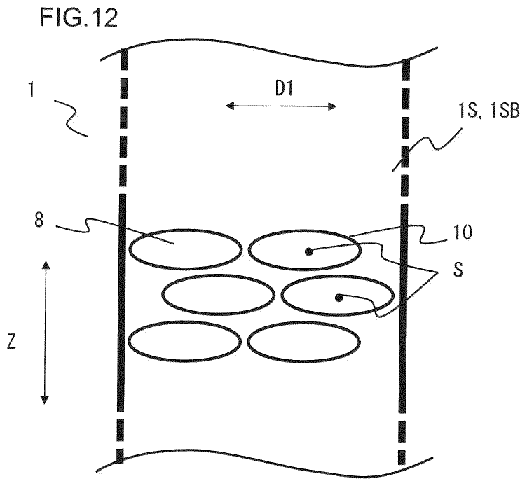

FIG. 12 shows a modified example of embodiment 5. In this case, the deformed regions 8, when viewed in the buckling direction X, may have a ridge 10 (outer edge) that is elliptical.

According to the probe for a probe card of embodiment 5, since the deformed regions 8 can be arranged at a high density, stress can be further distributed, enabling the provision of a probe for a probe card with high mechanical strength.

### Embodiment 6

Hereinafter, a probe for a probe card according to embodiment 6 will be described, focusing on differences from embodiments 1 to 5.

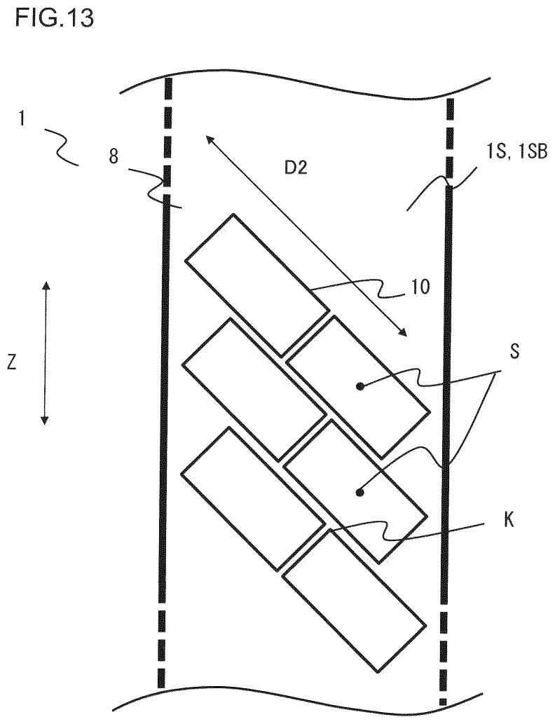

FIG. 13 is an enlarged partial view of the surface 1S of probe 1 perpendicular to the buckling direction X, showing another arrangement example of deformed regions 8.

A plurality deformed regions 8 are arranged in a predetermined direction D2 in a row relative to the longitudinal direction Z of the probe 1, with spacings P, and multiple rows are arranged. Here, the direction D2 is set to be oblique relative to the longitudinal direction Z of the probe 1.

In this example, the deformed regions 8 in each row have a rectangular ridge 10. The centers S of the deformed regions 8 in each row are aligned along the longitudinal direction Z of the probe 1, but at most two corners K are adjacent to each other. This example achieves the same effects as embodiment 4.

### Embodiment 7

Hereinafter, a probe for a probe card according to Embodiment 7 will be described, focusing on differences from Embodiments 1 to 6.

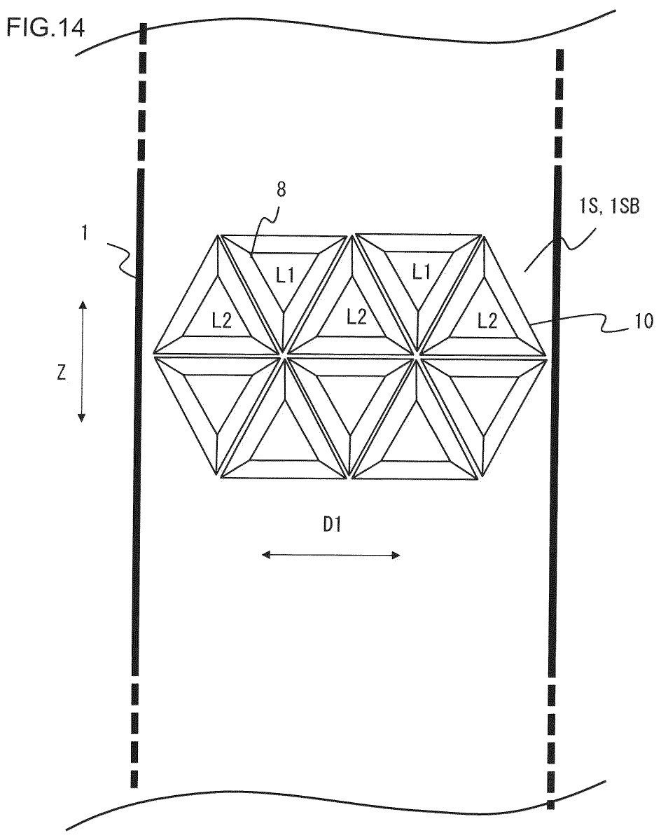

FIG. 14 is an enlarged view of a main part of a surface 1S of the probe 1 perpendicular to the buckling direction X, in which truncated triangular pyramid shaped recesses are provided.

A plurality deformed regions 8 are arranged in a predetermined direction D1 in a row relative to the longitudinal direction Z of the probe 1, with spacings P, and multiple rows are arranged. Here, direction D1 is perpendicular to the longitudinal direction Z of the probe 1.

The deformed regions 8 forming the first row L1 and the deformed regions 8 forming the second row L2 are arranged in an inverted manner along the vertical direction in FIG. 14. Additionally, the deformed regions 8 are recessed from the reference surface 1SB in a truncated triangular pyramid.

According to the probe for a probe card of Embodiment 7, the deformed regions 8 can be arranged at high density, allowing further stress distribution and providing a probe for a probe card with high mechanical strength. Additionally, the strength of the framework regions 9 can be reinforced.

### Embodiment 8

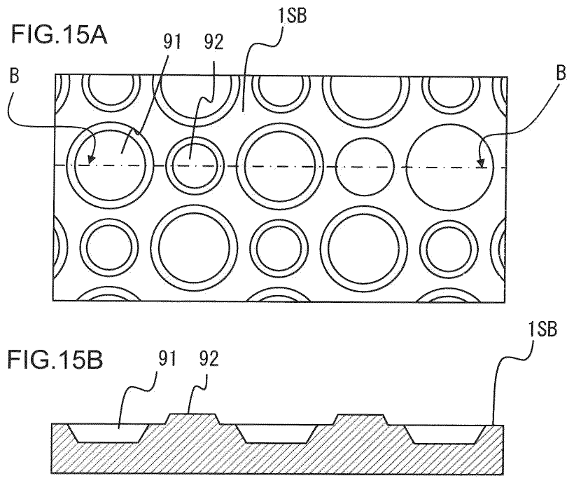

FIG. 15A is an enlarged view of a main part of a probe in which, in addition to truncated cone shaped recesses, truncated cone shaped protrusions are provided. FIG. 15B is a sectional view along line B-B in FIG. 15A. As shown in FIGS. 15A and 15B, the reference surface 1SB of the probe 1 is provided with first deformed regions 91, which are truncated cone shaped recesses with a first large diameter, and second deformed regions 92, which are truncated cone shaped protrusions with a second smaller diameter.

On the surface of the probe 1, the first deformed regions 91 are arranged in a staggered pattern, and the second deformed regions 92 are positioned in the spaces between the first deformed regions 91. With this arrangement of the first deformed regions 91 and the second deformed regions 92, stress is uniformly distributed, resulting in a probe with a highly durable structure. In this manner, the deformed regions may have a protruding shape from the reference surface 1SB or a combination of recessed and protruding shapes.

### Embodiment 9

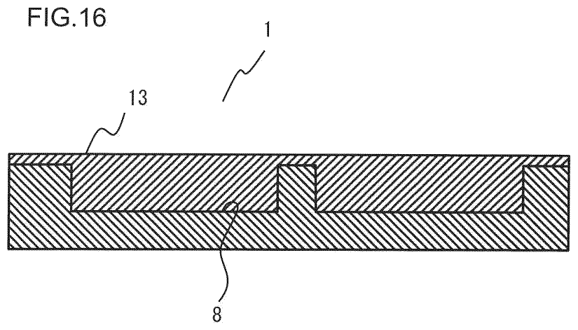

FIG. 16 shows a partial cross-sectional shape of a probe 1 according to Embodiment 9. As shown in FIG. 16, in this embodiment, a coating layer 13 is provided on the surface of the metal plate of the probe 1 described in Embodiments 1 to 8 to prevent foreign substances from adhering to the surface. Furthermore, even if foreign substances do adhere, the coating layer is designed to ensure they can be easily removed by providing a smooth covering over the metal plate surface. This configuration allows for solving the issue of foreign substance adhesion by applying a coating layer on a probe that has deformed regions in the form of recesses or protrusions on the surface of the metal plate.

The material of the coating layer 13 is preferably a resin layer that does not hinder the deformation of the metal plate. In particular, in Embodiments 1 to 5, where multiple deformed regions 8 in the form of recesses or protrusions are provided on the surface, adhesion of foreign substances is a concern. Therefore, applying a coating layer 13 to smooth the surface is effective in alleviating this concern. By providing multiple deformed regions 8 that are recessed shape or protruding shape and framework regions 9 on the surface of the conductive body and covering the surface with the coating layer 13, a probe 1 with high mechanical strength and resistance to foreign substance adhesion can be obtained. It should be noted that materials other than resin may also be used, provided that they are different from the material of the probe 1 structure.

Although the disclosure is described above in terms of various exemplary embodiments and implementations, it should be understood that the various features, aspects, and functionality described in one or more of the individual embodiments are not limited in their applicability to the particular embodiment with which they are described, but they can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 probe
1SB reference surface
10 ridge
101 area-expansion pattern region
102 stress-concentration region
13 coating layer
2 first guide plate
3 second guide plate
4 tip section
41 substrate
42 conductive layer
43 metal layer
5 electrode pad
51 first mold
52 second mold
53 metal plate
6 rear-end section
7 central section
8 deformed region
9 framework region
91 first deformed region
92 second deformed region
1S surface
X buckling direction
L1 first row
L2 Second row
L3 third row
L4 fourth row
K corner section
P spacing
D1, D2 predetermined direction

1. A probe for a probe card, wherein the probe is a vertical probe that buckles in a direction perpendicular to the longitudinal direction of a conductive metal plate, comprising:
a plurality of deformed regions arranged with spacings therebetween on the reference surface included in the plate surface perpendicular to a buckling direction, the outer edge of each deformed region being circular, ellipse, or polygonal, and the deformed region having a recessed shape or a protruding shape; and
a framework region provided at the boundary of adjacent deformed regions, wherein
a plurality of the deformed regions are arranged as a row with spacings therebetween in a predetermined direction relative to the lengthwise direction of the probe, and
a plurality of the rows are arranged with spacings there between, wherein
the plurality of deformed regions in the N-th row and the plurality of deformed regions in the (N+1)-th row are staggered along the predetermined direction.

2. The probe for a probe card according to claim 1, wherein
the predetermined direction is an oblique direction relative to the lengthwise direction of the probe.

3. (canceled)

4. The probe for a probe card according to claim 1, wherein
the predetermined direction is a direction perpendicular to the lengthwise direction of the probe.

5. (canceled)

6. The probe for a probe card according to claim 1, wherein
each of the deformed regions has any of the following shapes:
a polygonal prism shape,
a polygonal pyramid shape,
a cylindrical shape,
an elliptical cylindrical shape,
a conical shape, an elliptical conical shape, or
a truncated polygonal pyramid shape,
a truncated conical shape,
a truncated elliptical conical shape, wherein
the truncated shapes gradually increase in cross-sectional area toward the reference surface.

7. The probe for a probe card according to claim 1, wherein
the deformed regions are covered with a member made of a material different from the structural material of the probe.

8. The probe for a probe card according to claim 2, wherein
the deformed regions are covered with a member made of a material different from the structural material of the probe.

9. The probe for a probe card according to claim 4, wherein
the deformed regions are covered with a member made of a material different from the structural material of the probe.

10. The probe for a probe card according to claim 6, wherein
the deformed regions are covered with a member made of a material different from the structural material of the probe.
